(19) United States
(12) Patent Application Publication
(10) Pub. No.: US 2016/0365261 A1
(43) Pub. Date: Dec. 15, 2016

(54) PLASMA ETCHING DEVICE WITH DOPED QUARTZ SURFACES

(71) Applicant: Lam Research Corporation, Fremont, CA (US)

(72) Inventor: Sanket SANT, Fremont, CA (US)

(21) Appl. No.: 15/174,091

(22) Filed: Jun. 6, 2016

Related U.S. Application Data
(60) Provisional application No. 62/174,323, filed on Jun. 11, 2015.

(51) Int. Cl. H01L 21/67; H01J 37/32; H01L 21/687

(52) U.S. Cl. CPC H01L 21/67069; H01L 21/68735; H01J 37/32009; H01J 37/3244; H01J 2237/334

(57) ABSTRACT

An apparatus for processing a substrate is provided. A processing chamber is provided. A substrate support for supporting the substrate is within the processing chamber. An edge ring is on the substrate support, wherein the edge ring comprises nitrogen free doped quartz with a dopant of either AlO and YO or a dopant of LaO. A gas inlet for providing gas into the processing chamber is above a surface of the substrate. At least one electrode provides RF power into the processing chamber.

### CROSS REFERENCE TO RELATED APPLICATIONS

This application claims priority to U.S. Provisional Patent Application No. 62/174,323 filed on Jun. 11, 2015 and entitled “PLASMA ETCHING DEVICE WITH DOPED QUARTZ SURFACES” which is incorporated by reference herein.

### BACKGROUND

The present disclosure relates to the manufacturing of semiconductor devices. More specifically, the disclosure relates to plasma resistant parts used in manufacturing semiconductor devices.

During semiconductor wafer processing, plasma processing chambers are used to process semiconductor devices.

Descriptions and embodiments discussed in this background are not presumed to be prior art. Such descriptions are not an admission of prior art.

### SUMMARY

To achieve the foregoing and in accordance with the purpose of the present disclosure, an apparatus for processing a substrate is provided. A processing chamber is provided. A substrate support for supporting the substrate is within the processing chamber. An edge ring is on the substrate support, wherein the edge ring comprises nitrogen free doped quartz with a dopant of either AlO and YO or a dopant of LaO. A gas inlet for providing gas into the processing chamber is above a surface of the substrate. At least one electrode provides RF power into the processing chamber.

In another embodiment, an edge ring for use in a plasma processing chamber is provided. The edge ring comprises a nitrogen free doped quartz ring with a dopant of either AlO and YO or a dopant of LaO.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 schematically illustrates an example of a plasma processing chamber.

### DETAILED DESCRIPTION OF THE EMBODIMENTS

The present disclosure will now be described in detail with reference to a few embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

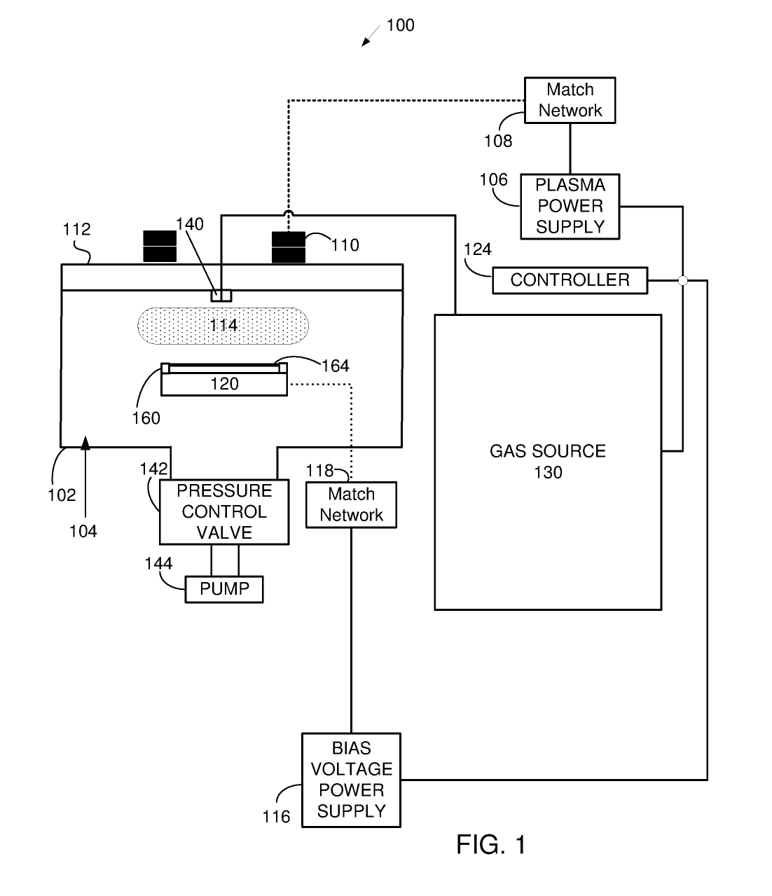

To facilitate understanding, FIG. 1 schematically illustrates an example of a plasma processing chamber 100 which may be used in an embodiment. The plasma processing chamber 100 includes a plasma reactor 102 having a plasma processing confinement chamber 104 therein. A plasma power supply 106, tuned by a match network 108, supplies power to a TCP coil 110 located near a power window 112 to create a plasma 114 in the plasma processing confinement chamber 104 by providing an inductively coupled power. The TCP coil (upper power source) 110 may be configured to produce a uniform diffusion profile within the plasma processing confinement chamber 104. For example, the TCP coil 110 may be configured to generate a toroidal power distribution in the plasma 114. The power window 112 is provided to separate the TCP coil 110 from the plasma processing confinement chamber 104 while allowing energy to pass from the TCP coil 110 to the plasma processing confinement chamber 104. A wafer bias voltage power supply 116 tuned by a match network 118 provides power to an electrode 120 to set the bias voltage on a substrate 164 which is supported by the electrode 120. A controller 124 sets points for the plasma power supply 106, gas source/gas supply mechanism 130, and the wafer bias voltage power supply 116.

The plasma power supply 106 and the wafer bias voltage power supply 116 may be configured to operate at specific radio frequencies such as, for example, 13.56 MHz, 27 MHz, 2 MHz, 60 MHz, 400 kHz, 2.54 GHz, or combinations thereof. Plasma power supply 106 and wafer bias voltage power supply 116 may be appropriately sized to supply a range of powers in order to achieve desired process performance. For example, in one embodiment, the plasma power supply 106 may supply the power in a range of 50 to 5000 Watts, and the wafer bias voltage power supply 116 may supply a bias voltage of in a range of 20 to 2000 V. In addition, the TCP coil 110 and/or the electrode 120 may be comprised of two or more sub-coils or sub-electrodes, which may be powered by a single power supply or powered by multiple power supplies.

As shown in FIG. 1, the plasma processing chamber 100 further includes a gas source/gas supply mechanism 130. The gas source 130 is in fluid connection with plasma processing confinement chamber 104 through a gas inlet, such as a gas injector 140. The gas injector 140 may be located in any advantageous location in the plasma processing confinement chamber 104, and may take any form for injecting gas. Preferably, however, the gas inlet may be configured to produce a “tunable” gas injection profile, which allows independent adjustment of the respective flow of the gases to multiple zones in the plasma process confinement chamber 104. The process gases and byproducts are removed from the plasma process confinement chamber 104 via a pressure control valve 142 and a pump 144, which also serve to maintain a particular pressure within the plasma processing confinement chamber 104. The pressure control valve 142 can maintain a pressure of less than 1 torr during processing. An edge ring 160 is placed around the wafer 164. The gas source/gas supply mechanism 130 is controlled by the controller 124. A Kiyo by Lam Research Corp. of Fremont, Calif., may be used to practice an embodiment.

Preferably the edge ring 160 comprises plasma resistant glass, such as doped quartz. More preferably, the edge ring 160 comprises a nitrogen free doped quartz. Most preferably, the edge ring 160 comprises a nitrogen free doped quartz with a dopant of aluminum oxide and yttrium oxide or a dopant of lanthanum oxide. In one embodiment, the percentage of dopant is between 6% to 20% by number of molecules. More preferably, the percentage of dopant is between 10% and 15%. Preferably, the ratio of aluminum to yttrium is in the range of 1:3 to 1:1 by number of molecules. Preferably, the doped quartz with a dopant of lanthanum oxide also has a dopant of aluminum oxide. Preferably, the ratio of aluminum to lanthanum is in the range of 5:13 to 15:13.

While this disclosure has been described in terms of several embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. An apparatus for processing a substrate, comprising
a processing chamber;
a substrate support for supporting the substrate within the processing chamber;
an edge ring on the substrate support, wherein the edge ring comprises nitrogen free doped quartz with a dopant of either AlO and YO or a dopant of LaO;
a gas inlet for providing gas into the processing chamber above a surface of the substrate; and
at least one electrode, for providing RF power into the processing chamber.

2. The apparatus, as recited in claim 1, wherein a percentage of dopant is between 6% to 20% inclusive.

3. The apparatus, as recited in claim 1, wherein the dopant is aluminum oxide and yttrium oxide with an aluminum oxide to yttrium oxide ratio between 1:3 to 1:1 inclusive.

4. The apparatus, as recited in claim 1, wherein the dopant comprises lanthanum oxide.

5. The apparatus, as recited in claim 4, wherein the dopant further comprises aluminum oxide.

6. The apparatus, as recited in claim 5, wherein an aluminum oxide to lanthanum oxide ratio is between 5:13 to 15:13 inclusive.

7. The apparatus, as recited in claim 1, wherein the percentage of dopant is between 10% to 15% inclusive.

8. An edge ring for use in a plasma processing chamber comprising a nitrogen free doped quartz ring with a dopant of either AlO and YO or a dopant of LaO.

9. The edge ring, as recited in claim 8, wherein a percentage of dopant is between 6% to 20% inclusive.

10. The edge ring, as recited in claim 8, wherein the dopant is aluminum oxide and yttrium oxide with an aluminum oxide to yttrium oxide ratio between 1:3 to 1:1 inclusive.

11. The edge ring, as recited in claim 8, wherein the dopant comprises lanthanum oxide.

12. The edge ring, as recited in claim 11, wherein the dopant further comprises aluminum oxide.

13. An edge ring for use in a plasma processing chamber comprising a doped quartz ring.

14. The edge ring, as recited in claim 13, wherein the doped quartz ring is a nitrogen free doped quartz ring.

15. The edge ring, as recited in claim 13, wherein the doped quartz ring is doped with a dopant comprising either AlO and YO or a dopant of LaO.

16. An apparatus for processing a substrate, comprising a processing chamber;
a substrate support for supporting the substrate within the processing chamber;
an edge ring on the substrate support, wherein the edge ring comprises a doped quartz;
a gas inlet for providing gas into the processing chamber above a surface of the substrate; and
at least one electrode, for providing RF power into the processing chamber. The edge ring, as recited in claim 16, wherein the doped quartz ring is a nitrogen free doped quartz ring.

18. The edge ring, as recited in claim 16, wherein the doped quartz ring is doped with a dopant comprising either AlO and YO or a dopant of LaO.
